(19) United States
(12) Patent Application Publication
(10) Pub. No.: US 2025/0323279 A1
(43) Pub. Date: Oct. 16, 2025

(54) COMPOSITE CURRENT COLLECTOR AND PREPARATION METHOD THEREFOR, AND APPLICATION THEREOF IN LITHIUM-ION BATTERIES

(71) Applicant: ADVANCED MATERIALS TECHNOLOGY (BEIJING) CO., LTD., Beijing (CN)

(72) Inventors: Xiufeng GONG, Beijing (CN); Xinsen SUN, Beijing (CN); Gang LIU, Beijing (CN); Dongliang LI, Beijing (CN); Yanru JIANG, Beijing (CN); Hongfeng JIANG, Beijing (CN); Yongwei LI, Beijing (CN)

(73) Assignee: ADVANCED MATERIALS TECHNOLOGY (BEIJING) CO., LTD., Beijing (CN)

(21) Appl. No.: 19/246,071

(22) Filed: Jun. 23, 2025

Related U.S. Application Data
(63) Continuation of application No. PCT/CN2023/141283, filed on Dec. 22, 2023.

(30) Foreign Application Priority Data
Dec. 23, 2022 (CN) 202211665009.5
Dec. 23, 2022 (CN) 202211665082.2

(51) Int. Cl. H01M 4/66; H01M 4/04

(52) U.S. Cl. CPC H01M 4/667; H01M 4/0426; H01M 4/661; H01M 4/668

(57) ABSTRACT

In a lithium-ion battery, a current collector includes an upper metal layer, a lower metal layer, and a polymer layer between the upper metal layer and the lower metal layer. Specifically, surface densities of the upper and lower metal layers are each independently 0.5-30 g/m², and grain sizes of the metal respectively contained in the upper and lower metal layers range from 50 nm to 5 μm; and the sheet resistance of the current collector is 5-5,000 mΩ/□, and the resistivity is 1-5 μΩ·cm. The upper and lower metal layers of the current collector according to the present disclosure are featured by low residual stress, low defects, light weight, ultra-thin thickness, and high conductivity, and can be better adapted to electrochemical devices.

### CROSS-REFERENCE TO RELATED APPLICATIONS

The present application is based on the Chinese application with the CN application number of 202211665009.5 filed on Dec. 23, 2022 and the Chinese application with the CN application number 202211665082.2 filed on Dec. 23, 2022, and claims their priority. The disclosure content of these CN applications is introduced into the present application as a whole.

### TECHNICAL FIELD

The present disclosure relates to the field of current collector technology, and specifically to a composite current collector and a preparation method therefor, and an application thereof in lithium-ion batteries.

### BACKGROUND

The current collector, as one of the important components of lithium-ion batteries, carries active substances, and collects and conducts electrons. An ideal lithium-ion battery current collector should meet the following requirements: (1) high conductivity; (2) good chemical and electrochemical stability; (3) high mechanical strength; (4) good compatibility and bonding with electrode active materials; (5) cheap and easy to obtain; and (6) light weight.

For traditional current collectors, generally, aluminum foil is used as the cathode current collector, and copper foil is used as the anode current collector. However, copper foil and aluminum foil are difficult to meet the increasingly high performance requirements on lithium-ion battery current collectors. Composite current collectors have been developed to improve the performance of current collectors. A polymer layer is generally taken as the substrate of the composite current collector, which is prepared by depositing metallic copper or metallic aluminum on the polymer layer.

A current collector is one of the important components of a lithium-ion battery, as it not only can carry active materials, but also collect and output electrons generated by electrode active substances. The future development trend is lithium-ion batteries with light weight, low cost, and high energy density, so current collectors need to have properties such as ultra-high purity, high conductivity, high strength, high flexibility, and ultra-thin thickness.

Due to the limitations of preparation technology, it is difficult to reduce the thicknesses of copper foil and aluminum foil, which cannot meet people's performance requirements for current collectors. Depositing conductive metal Cu or Al on a polymer layer (for example, PET) can optimize the various properties of the copper foil or aluminum foil current collector. However, conductive metal layers deposited on the polymer layer generally have defects such as small grains, many grain boundaries, many lattice structural defects (such as cavities and dislocations), and large thermal stress and growth stress. Therefore, the conductivity of current collectors still needs to be further improved.

### SUMMARY

The purpose of the present disclosure is to solve the problem of limited conductivity of composite current collectors in the prior art, and provide a composite current collector and a preparation method therefor, and an application thereof in lithium-ion batteries.

In order to achieve the above-mentioned purposes, in a first aspect, the present disclosure provides a composite current collector including an upper metal layer, a lower metal layer, and a polymer layer between the upper metal layer and the lower metal layer. Specifically, surface densities of the upper metal layer and the lower metal layer are each independently 0.5-30 g/m², and grain sizes of the metal respectively contained in the upper metal layer and the lower metal layer range from 50 nm to 5 μm; and the sheet resistance of the current collector is 5-5,000 mΩ/□, and the resistivity is 1-5 μΩ·cm.

In a second aspect, the present disclosure provides a method for preparing the composite current collector, including the following steps:
(1) using a conductive metal source as a deposition raw material, depositing an upper conductive metal film on the upper surface of the polymer layer, and depositing a lower conductive metal film on the lower surface of the polymer layer, to obtain a current collector intermediate; and
(2) performing a vacuum heat treatment to the current collector intermediate to modify the upper conductive metal film and the lower conductive metal film, to obtain a composite current collector including an upper metal layer, a polymer layer, and a lower metal layer in sequence.

In a third aspect, the present disclosure provides an application of the composite current collector described in the first aspect of the present disclosure or the composite current collector prepared by the method described in the second aspect of the present disclosure in lithium-ion batteries.

Through the above technical solutions, the beneficial technical effects achieved by the present disclosure are as follows:
1) the upper metal layer and the lower metal layer of the composite current collector according to the present disclosure are featured by low residual stress and low defects, resulting in not only light weight and ultra-thin thickness, but also high conductivity of the current collector, and can be better adapted to electrochemical devices;
2) in the method of preparing the composite current collector according to the present disclosure, vacuum heat treatment is used to mitigate lattice defects of the metal film, release the residual stress, induce grain growth, and reduce the scattering effect of grain boundaries on free electrons, which can significantly improve the conductivity of the composite current collector;
3) the composite current collector according to the present disclosure has the advantages of high conductivity, high strength, high flexibility, light weight, and ultra-thin thickness. Lithium-ion batteries prepared from the composite current collector according to the present disclosure are featured by light weight, low cost, and high energy density; and
4) the method of preparing the composite current collector according to the present disclosure is simple to operate and suitable for promotion.

### BRIEF DESCRIPTION OF DRAWINGS

The drawings of the specification forming a part of the present disclosure are used to provide a further understanding of the present disclosure. The exemplary embodiments of the present disclosure and their descriptions are only for explaining the present disclosure and do not unduly limit the present disclosure. Among the figures:

FIG. 1 is a schematic diagram of the structure of the current collector according to the present disclosure;

FIG. 2 is a cross-sectional TEM image of the aluminum composite current collector obtained in Embodiment 2;

FIG. 3 is a cross-sectional TEM image of the aluminum composite current collector in Embodiment 4 before heat treatment;

FIG. 4 is a cross-sectional TEM image of the aluminum composite current collector (after heat treatment) in Embodiment 4;

FIG. 5 is a cross-sectional TEM image of the copper composite current collector obtained in Embodiment 9;

FIG. 6 is a cross-sectional TEM image of the copper composite current collector obtained in Embodiment 13;

FIG. 7 is a schematic diagram of the structure of a composite current collector according to a preferred embodiment of the present disclosure; and

FIG. 8 is a schematic diagram of the structure of a composite current collector according to another preferred embodiment of the present disclosure.

20. substrate; 21. upper bonding layer; 22. lower bonding layer; 31. upper conductive layer; 32. lower conductive layer; 41. upper primer layer; 42. lower primer layer; 1. polymer layer; 2. upper metal layer; 3. lower metal layer.

### DETAILED DESCRIPTION OF THE EMBODIMENTS

The endpoints and any values of the range disclosed herein are not limited to the exact range or value, which should be understood to include values close to these ranges or values. For numerical ranges, one or more new numerical ranges may be obtained by combining the endpoint values of each range, between the endpoint values of each range and individual point values, and between individual point values, which shall be deemed to be specifically disclosed herein.

The names of some layers in the composite current collector of the present disclosure are different from the reference numerals, but they represent the same meaning. Specifically, the substrate 20 is essentially equivalent to the polymer layer 1, the upper conductive layer 31 is essentially equivalent to the upper metal layer 2, and the lower conductive layer 32 is essentially equivalent to the lower metal layer 3.

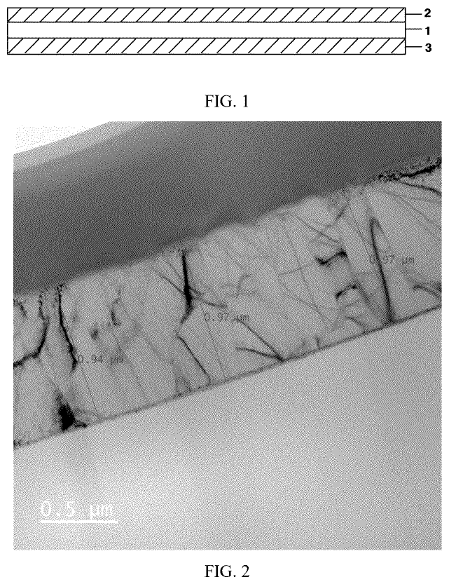

In a first aspect, the present disclosure provides a composite current collector as shown in FIG. 1, including an upper metal layer 2, a lower metal layer 3, and a polymer layer 1 between the upper metal layer 2 and the lower metal layer 3. Specifically, surface densities of the upper metal layer 2 and the lower metal layer 3 are each independently 0.5-30 g/m², and grain sizes of the metal respectively contained in the upper metal layer 2 and the lower metal layer 3 range from 50 nm to 5 km; and the sheet resistance of the current collector is 5-5,000 mΩ/□, and the resistivity is 1-5 μΩ·cm.

In the present disclosure, surface densities of the upper metal layer 2 and the lower metal layer 3 are each independently 0.5-30 g/m², for example, 0.5 g/m², 1 g/m², 3 g/m², 5 g/m², 8 g/m², 10 g/m², 15 g/m², 20 g/m², 25 g/m², 30 g/m², and any value in a range between any two numerical values.

When both the upper metal layer and the lower metal layer are made of aluminum, surface densities of the upper metal layer and the lower metal layer are preferably in the range of 4-20 g/m², and more preferably 7-18 g/m².

When both the upper metal layer and the lower metal layer are made of copper, surface densities of the upper metal layer and the lower metal layer are preferably in the range of 4-30 g/m², and more preferably 7-28 g/m².

In the present disclosure, grain sizes of the metal respectively contained in the upper metal layer and the lower metal layer range from 50 nm to 5 μm, for example, 50 nm, 100 nm, 150 nm, 200 nm, 250 nm, 300 nm, 400 nm, 500 nm, 600 nm, 700 nm, 800 nm, 900 nm, 1 μm, 2 μm, 3 μm, 4 μm, 5 μm, and any value in a range between any two numerical values, and preferably from 300 nm to 3 μm.

In the present disclosure, the sheet resistance of the current collector is 5-5,000 mΩ/□, for example, 5 mΩ/□, 10 mΩ/□, 50 mΩ/□, 100 mΩ/□, 150 mΩ/□, 200 mΩ/□, 300 mΩ/□, 400 mΩ/□, 500 mΩ/□, 600 mΩ/□, 700 mΩ/□, 800 mΩ/□, 900 mΩ/□, 1,000 mΩ/□, 1,500 mΩ/□, 2,000 mΩ/□, 2,500 mΩ/□, 3,000 mΩ/□, 3,500 mΩ/□, 4,000 mΩ/□, 4,500 mΩ/□, 5,000 mΩ/□, and any value in a range between any two numerical values, and preferably 10-1,000 mΩ/□.

In the present disclosure, the resistivity is 1-5 μΩ·cm, for example, 1 μΩ·cm, 1.5 μΩ·cm, 2 μΩ·cm, 2.5 μΩ·cm, 3 μΩ·cm, 3.5 μΩ·cm, 4 μΩ·cm, 4.5 μΩ·cm, 5 μΩ·cm, and any value in the range between any two numerical values.

Compared with composite current collectors of the prior art, the conductivity of the current collector according to the present disclosure can be more than 8% higher, and the resistivity can be more than 8% smaller. For example, when the metal layer is made of copper, the resistivity of the current collector according to the present disclosure can be 30% smaller, and when the metal layer is made of aluminum, the resistivity of the current collector according to the present disclosure can be 10% smaller.

The current collector according to the present disclosure is significantly superior to existing current collectors in terms of sheet resistance and resistivity. In the present disclosure, grain sizes are tested by transmission electron microscopy (TEM), and the sheet resistance and conductivity are tested in accordance with GB/T 1552-1995 Test Method for Measuring Resistivity of Monocrystal Silicon and Germanium with a Collinear Four-probe Array. In the present disclosure, the grain sizes refer to sizes of metal particles in the upper metal layer 2 and the lower metal layer 3.

In a preferred embodiment method, the material of the polymer layer includes one or more constituents selected from the group consisting of polyethylene (PE), biaxially oriented polypropylene (BOPP), polyethylene terephthalate (PET), polyethylene naphthalate (PEN), poly(p-phenylene terephthalamide) (PPTA), polyimide (PI), polycarbonate (PC), polyetheretherketone (PEEK), polyoxymethylene (POM), poly(p-phenylene sulfide) (PPS), poly(p-phenylene oxide) (PPO), polyvinyl chloride (PVC), polyamide (PA), and polytetrafluoroethylene (PTFE), and preferably the material of the polymer layer is selected from polyethylene terephthalate film, biaxially oriented polypropylene film, and polyimide film with a temperature resistance rating of greater than or equal to 400° C.

In a preferred embodiment method, the material of the polymer layer is selected from polyethylene terephthalate film, biaxially oriented polypropylene film, and polyimide film with a temperature resistance rating of greater than or equal to 400° C. Among them, all polyethylene terephthalate films and biaxially oriented polypropylene films that can be obtained by those skilled in the art from the prior art can be used in the present disclosure.

In a preferred embodiment method, the thickness of the polymer layer is 0.001-0.5 mm, for example, 0.001 mm, 0.005 mm, 0.01 mm, 0.1 mm, 0.2 mm, 0.3 mm, 0.4 mm, 0.5 mm, or any value between any two above-mentioned numerical values, and preferably 0.003-0.25 mm.

In a preferred embodiment method, the upper metal layer and the lower metal layer are made of copper or aluminum.

In a preferred embodiment method, bonding forces between the upper metal layer and the polymer layer and between the lower metal layer and the polymer layer are 0.5-20 N/15 mm.

In the present disclosure, bonding forces are tested in accordance with GB/T 2792-2014 Measurement of Peel Adhesion Properties for Adhesive Tapes.

In a preferred embodiment method, the upper metal layer 2 and the lower metal layer 3 are made of copper or aluminum. Specifically, in the present disclosure, when the upper metal layer 2 and the lower metal layer 3 are made of aluminum, the current collector is a cathode current collector, and when the upper metal layer 2 and the lower metal layer 3 are made of copper, the current collector is an anode current collector.

In a preferred embodiment method, the material of the polymer layer 1 is selected from polyethylene terephthalate film, biaxially oriented polypropylene film, and polyimide film with a temperature resistance rating of greater than or equal to 400° C. Among them, the biaxially oriented polypropylene film (BOPP) described in the present disclosure is made by co-extruding polypropylene particles to form a sheet and then stretching it in two perpendicular directions (known as biaxial orientation). All polyethylene terephthalate films and biaxially oriented polypropylene films that can be obtained by those skilled in the art from the prior art can be used in the present disclosure.

In a preferred embodiment method, thicknesses of the upper metal layer 2 and the lower metal layer 3 are each independently 100-1,500 nm. Specifically, thicknesses of the upper metal layer 2 and the lower metal layer 3 can be each independently 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1,000 nm, 1,200 nm, 1,500 nm, or any value between any two above-mentioned numerical values, and preferably 100-1,000 nm.

In a preferred embodiment method, the thickness of the polymer layer 1 is 0.001-0.5 mm, for example, 0.001 mm, 0.005 mm, 0.01 mm, 0.1 mm, 0.2 mm, 0.3 mm, 0.4 mm, 0.5 mm, or any value between any two above-mentioned numerical values, and preferably 0.003-0.25 mm.

In a preferred embodiment method, the composite current collector further includes bonding layers, which are attached to the two surfaces of the polymer layer, and the upper metal layer and the lower metal layer are respectively on the corresponding bonding layers and are arranged away from the polymer layer; and each of the bonding layers is obtained by curing an adhesive comprising a main adhesive, a secondary adhesive, and a solvent, among which the main adhesive includes one or more constituents selected from the group consisting of maleic acid, methylene succinic acid, ethylene succinic acid, methylene adipic acid, guanidinoacetic acid, thioglycolic acid, acrylic acid, methacrylic acid, acrylamide, and glyoxal; and the secondary adhesive includes one or more constituents selected from the group consisting of styrene, polystyrene, polyurethane, isocyanate, ethyl acrylate, styrene-butadiene rubber, phenolic resin, urea-formaldehyde resin, epoxy resin, and methyl acrylate.

Among them, in the present disclosure, according to transportation and storage requirements, the main adhesive, the auxiliary adhesive, and the solvent can be packaged separately, and mixed before being used, or can be directly mixed before being packaged.

In the present disclosure, the main adhesive and the auxiliary adhesive undergo in-situ polymerization reaction, and the generated polymer product not only can tightly combine the substrate and conductive layers together to improve the bonding strength between the substrate and conductive layers, but also improve the mechanical properties of the substrate, thereby improving the mechanical properties of the composite current collector.

Through the above technical solutions, the beneficial technical effects achieved by the present disclosure are as follows:
1) the adhesive according to the present disclosure can be used in preparing composite current collectors, to significantly improve the mechanical properties of composite current collectors, and enhance the bonding strength between the substrate and conductive layers or between the substrate and primer layers for composite current collectors;
2) the composite current collector provided according to the present disclosure has large bonding forces between layers, good mechanical strength, good safety performance, and long service life; and
3) the method for preparing the composite current collector according to the present disclosure is simple to operate and suitable for industrial promotion.

In a preferred embodiment method, the main adhesive includes one or two constituents selected from the group consisting of methylene succinic acid, glyoxal, thioglycolic acid, maleic acid, and guanidinoacetic acid, preferably includes any two constituents selected from the group consisting of methylene succinic acid, glyoxal, thioglycolic acid, maleic acid, and guanidinoacetic acid, further preferably includes methylene succinic acid and any one constituent selected from the group consisting of glyoxal, thioglycolic acid, maleic acid, and guanidinoacetic acid, and more further preferably includes methylene succinic acid and glyoxal. Specifically, the mass ratio of methylene succinic acid to glyoxal is 1:0.5-1.5, and preferably 1:0.8-1.2.

In a preferred embodiment method, the mass content of the main adhesive is 1% to 20% of the total mass of the adhesive.

Specifically, in the present disclosure, the mass content of the main adhesive can be 1%, 1.5%, 2%, 2.5%, 3%, 3.5%, 4%, 4.5%, 5%, 5.5%, 6%, 6.5%, 7%, 7.5%, 8%, 8.5%, 9%, 9.5%⁰, 1%, 11%1, 2%1, 3%1, 4%1, 5%1, 6%1, 7%1, 8%, 19%, 20%, or any value in a range between any two of these numerical values. Preferably, the mass content of the main adhesive is 1% to 10% of the total mass of the adhesive, and further preferably 1% to 4%.

In a preferred embodiment method, the mass of the auxiliary adhesive is 0.5% to 15% of the mass of the main adhesive.

Specifically, in the present disclosure, the mass of the auxiliary adhesive is 0.5%, 1%, 1.5%, 2%, 2.5%, 3%, 3.5%, 4%, 4.5%, 5%, 5.5%, 6%, 6.5%, 7%, 7.5%, 8%, 8.5%, 9%, 9.5%, 10%, 11%, 12%, 13%, 14%, 15%, or any value in a range between any two above-mentioned numerical values, of the mass of the main adhesive. Preferably, the mass of the auxiliary adhesive is 0.5% to 6% of the mass of the main adhesive, and further preferably 1% to 3%.

In a preferred embodiment method, the mass content of the auxiliary binder is 0.01% to 0.4%, and preferably 0.03% to 0.1%.

In a preferred embodiment method, the auxiliary adhesive includes one or more constituents selected from the group consisting of epoxy resin, styrene, isocyanate, and methyl acrylate, and preferably epoxy resin and/or styrene. Among them, the epoxy resin is preferably a liquid epoxy resin.

Specifically, in the process of preparing the composite current collector, before depositing other layers on the polymer film (substrate) by magnetron sputtering or evaporation, the adhesive according to the present disclosure can be first coated on the polymer layer, and the adhesive will be cured on the polymer layer to form bonding layers, which not only can improve the connection strength between the polymer layer and the deposited layers, but also reduce the bombardment of metal particles on the polymer layer during magnetron sputtering and evaporation, to significantly improve the mechanical properties of the composite current collector, and improve the stability and safety of lithium-ion batteries.

Specifically, the present disclosure does not make special restrictions on molecular weights of epoxy resin, polystyrene, polyurethane, styrene-butadiene rubber, phenolic resin, and urea-formaldehyde resin, and those skilled in the art can choose according to actual needs.

In a preferred embodiment method, the solvent is made of anhydrous ethanol and/or water, and preferably anhydrous ethanol.

In a preferred embodiment method, the bonding layers include an upper bonding layer and a lower bonding layer. Specifically, the upper bonding layer is on the upper surface of the substrate, and the lower bonding layer is on the lower surface of the substrate.

In a preferred embodiment method, the upper bonding layer and the lower bonding layer are respectively and independently obtained by curing an adhesive including a main adhesive, an auxiliary adhesive, and a solvent.

In a preferred embodiment method, the upper bonding layer and the lower bonding layer are made of the same material and have the same thickness. Specifically, in the present disclosure, the upper bonding layer and the lower bonding layer can be made of the same or different materials and have the same or different thicknesses, and preferably be made of the same material and have the same thickness.

In a preferred embodiment method, the conductive layers are made of copper or aluminum. Specifically, in the present disclosure, when conductive layers are made of copper, the composite current collector is an anode current collector; and when conductive layers are made of aluminum, the composite current collector is a cathode current collector.

In a preferred embodiment method, the conductive layers include an upper conductive layer and a lower conductive layer. Specifically, the upper conductive layer is on the upper bonding layer, and the lower conductive layer is on the lower bonding layer.

In a preferred embodiment method, the upper conductive layer and the lower conductive layer are made of the same material and have the same thickness. Specifically, in the present disclosure, the upper conductive layer and the lower conductive layer are made of the same material, and can have the same or different thicknesses, and preferably the same thickness.

In a preferred embodiment method, the composite current collector further includes primer layers, specifically, each of the primer layers is between a bonding layer and a conductive layer.

In a preferred embodiment method, primer layers include an upper primer layer and a lower primer layer. Specifically, the upper primer layer is between the upper bonding layer and the upper conductive layer, and the lower primer layer is between the lower bonding layer and the lower conductive layer.

In a preferred embodiment method, the material of the upper primer layer and the material of the lower primer layer respectively and independently include one or more constituents selected from the group consisting of nickel, nickel-chromium alloy, and aluminum oxide, and preferably nickel-chromium alloy. Specifically, the mass ratio of nickel to chromium in the nickel-chromium alloy is 2-5:1.

In a preferred embodiment method, the upper primer layer and the lower primer layer are made of the same material and have the same thickness. Specifically, in the present disclosure, the upper primer layer and the lower primer layer can be made of the same or different materials and have the same or different thicknesses, and preferably be made of the same material and have the same thickness.

In a preferred embodiment method, the thickness of the substrate is 2-12 μm, for example, 2 μm, 3 μm, 4 μm, 5 μm, 6 μm, 7 μm, 8 am, 9 am, 10 am, 11 μm, 12 μm, and any value between any two numerical values, and preferably 5-6 am.

In a preferred embodiment method, thicknesses of the upper bonding layer and the lower bonding layer are respectively and independently 0.2-1 μm, for example, 0.2 μm, 0.25 μm, 0.3 μm, 0.35 μm, 0.4 am, 0.45 μm, 0.5 μm, 0.55 am, 0.6 am, 0.65 am, 0.7 μm, 0.75 μm, 0.8 μm, 0.85 μm, 0.9 μm, 0.95 am, 1 am, and any value between any two numerical values, and preferably 0.2-0.4 μm.

In a preferred embodiment method, thicknesses of the upper conductive layer and the lower conductive layer are respectively and independently 0.1-1.5 μm, for example, 0.1 μm, 0.2 μm, 0.3 μm, 0.4 μm, 0.5 μm, 0.6 μm, 0.7 μm, 0.8 am, 0.9 am, 1 μm, 1.1 μm, 1.2 μm, 1.3 μm, 1.4 μm, 1.5 μm, and any value between any two numerical values, and preferably 0.8-1.2 μm.

In a preferred embodiment method, thicknesses of the upper primer layer and the lower primer layer are respectively and independently 0.01-0.1 μm, for example, 0.01 μm, 0.02 μm, 0.03 μm, 0.04 μm, 0.05 μm, 0.06 μm, 0.07 μm, 0.08 am, 0.09 am, 0.1 μm, and any value between any two numerical values, and preferably 0.01-0.04 μm.

In a preferred embodiment method, bonding forces between conductive layers and the substrate or between primer layers and the substrate are 0.5-20 N/15 mm, preferably 5-10 N/15 mm, and further preferably 6-7.5 N/15 mm. Specifically, bonding forces are tested in accordance with GB/T 2792-2014.

In a preferred embodiment method, the tensile strength of the composite current collector is 150-400 MPa. Specifically, in the present disclosure, when the composite current collector is an anode current collector, the tensile strength of the composite current collector is 200-400 MPa; and when the composite current collector is a cathode current collector, the tensile strength of the composite current collector is 150-400 MPa. Specifically, tensile strengths are tested in accordance with HG/T 2580-2008.

Specifically, the tensile strength of the substrate itself is 150-400 MPa. When primer layers and/or conductive layers are evaporated onto the substrate, the surface of the polymer film is easily bombarded by metal particles during magnetron sputtering or evaporation, resulting in a decrease of 50-100 MPa in the tensile strength of the polymer film. In the present disclosure, the inventors have found in research that the adhesive according to the present disclosure can be used to repair mechanical damages of the substrate, restore mechanical properties of the substrate to the original level, or even better than the original level, thereby significantly improving mechanical properties of the composite current collector, extending the service life of the composite current collector, and broadening the application range of the composite current collector.

In a preferred embodiment method, the longitudinal tensile strength (MD) of the composite current collector is 210-240 MPa, and preferably 220-228 MPa; and the transverse tensile strength (TD) of the composite current collector is 195-220 MPa, and preferably 202-212 MPa.

In a second aspect, the present disclosure provides a method for preparing the composite current collector, including the following steps:
(1) using a conductive metal source as a deposition raw material, depositing an upper conductive metal film on the upper surface of the polymer layer, and depositing a lower conductive metal film on the lower surface of the polymer layer, to obtain a current collector intermediate; and
(2) performing a vacuum heat treatment to the current collector intermediate to modify the upper conductive metal film and the lower conductive metal film, to obtain a composite current collector including an upper metal layer, a polymer layer, and a lower metal layer in sequence.

In the present disclosure, the conductive metal source is a conductive metal material, including a single metal, an alloy, a composite metal, and so on. In the present disclosure, the conductive metal source is used as the evaporation source. The evaporation source refers to a conductive metal material that is heated and vaporized in a vacuum evaporation chamber. The substrate refers to a pre-evaporated film material, such as a polymer layer.

Specifically, in the present disclosure, the vacuum heat treatment described in step (2) can induce changes in the metal crystal structure on the one hand, transforming from fibrous structures to conical structures, columnar crystal structures, or even equiaxed crystal structures, resulting in the disappearance of some fine grain boundaries; on the other hand, it can induce the growth of fine grains, mitigate lattice defects, release residual stress, and make the upper metal layer and the lower metal layer be featured by low residual stress and low defects.

According to the present disclosure, vacuum heat treatment is used to give particles in the conductive metal film appropriate energy, such as increasing the heat treatment temperature and applying bias voltage, which can induce changes in the metal crystal structure. For vacuum heat treatment, the low temperature stage recovery can release the stress, induce the tendency of fine grains to grow, and mitigate lattice defects; and copper or aluminum undergoes recrystallization and grain growth in the temperature range of 270-600° C.

Vacuum heat treatment can improve the conductivity, bonding force and surface density of materials. That is to say, heat treatment reduces the defects of metal films, increases the thermal diffusion movement between atoms, and makes metal films denser. This is reflected in the material properties, such as reduced sheet resistance, reduced resistivity, increased bonding force, and increased surface density.

Through the heat treatment of the method according to the present disclosure, grain sizes can grow from tens of nanometers before heat treatment to hundreds of nanometers, for example, 300-500 nm, the resistivity can be increased by 2% to 10%, and the sheet resistance is reduced by 3-5 mΩ/sq. For example, at a same position, it was found in detection that the grain size was 30 nm before heat treatment, and 300 nm after heat treatment; and the sheet resistance was 38 mΩ/sq and the resistivity was 3.75 μΩ·cm before heat treatment, and respectively 30.85 mΩ/sq and 3.03 μΩ·cm the resistivity after heat treatment. It can be seen that heat treatment will bring very obvious improvement.

In a preferred embodiment method, the material of the polymer film is selected from polyethylene terephthalate film, biaxially oriented polypropylene film, and polyimide film with a temperature resistance rating of greater than or equal to 400° C. Among them, all polyethylene terephthalate films and biaxially oriented polypropylene films that can be obtained by those skilled in the art from the prior art can be used in the present disclosure.

In a preferred embodiment method, the thickness of the polymer film is 0.001-0.5 mm, for example, 0.001 mm, 0.005 mm, 0.01 mm, 0.1 mm, 0.2 mm, 0.3 mm, 0.4 mm, 0.5 mm, or any value between any two above-mentioned numerical values, and preferably 0.003-0.25 mm.

In a preferred embodiment method, the thickness of the upper conductive metal film is 100-1,500 nm, and preferably 100-1,000 nm; and the thickness of the lower conductive metal film is 100-1,500 nm, and preferably 100-1,000 nm.

In a preferred embodiment method, the conductive metal source is made of aluminum wires with a purity higher than or equal to 3N or copper wires with a purity higher than or equal to 3N, where 3N means that the purity is 99.9 wt %. An aluminum wire with a purity higher than or equal to 3N refers to an aluminum wire with a purity higher than 99.9%, and a copper wire with a purity higher than or equal to 3N refers to a copper wire with a purity higher than 99.9 wt %.

In a preferred embodiment method, the depositing described in step (1) is carried out by using a method selected from vacuum evaporation coating, vacuum sputtering coating, vacuum ion coating, and vacuum chemical vapor deposition coating, and preferably vacuum evaporation coating. In step (1) of the present disclosure, an upper conductive metal film and a lower conductive metal film are deposited on the upper surface and the lower surface of the polymer layer respectively and independently by using the above-mentioned operation method.

In a preferred embodiment method, the vacuum evaporation coating comprises: turning on the evaporation source current, heating the conductive metal source, and depositing an upper conductive metal film and a lower conductive metal film on the surface of the polymer film.

In a preferred embodiment method, the operating conditions of the vacuum evaporation coating include:
a vacuum degree higher than 10⁻³ Pa; a cold roller temperature of −25° C. to 35° C., for example, −25° C., −15° C., −5° C., 0° C., 10° C., 20° C., 25° C., 30° C., 35° C., or any value between any two above-mentioned numerical values; an ES distance of greater than or equal to 50 mm, for example, 50 mm, 55 mm, 60 mm, 70 mm, 80 mm, 100 mm, 120 mm, or any value between any two above-mentioned numerical values, and preferably 50-500 mm; and an evaporation temperature of higher than or equal to 800° C., for example, 800° C., 850° C., 900° C., 1,000° C., 1,100° C., 1,200° C., 1,500° C., or any value between any two above-mentioned numerical values, and preferably 800-2,000° C.

The vacuum degree refers to the rarefaction of gas under vacuum state. The smaller the value is, the thinner the gas will be, and the higher the vacuum degree will be.

In the present disclosure, the ES distance refers to the distance between the evaporation source and the substrate.

The evaporation source refers to a conductive metal material that is heated and vaporized in a vacuum evaporation chamber. The substrate refers to a pre-evaporated film material, such as a polymer film.

In a preferred embodiment method, the operating conditions of the vacuum heat treatment described in step (2) include: a vacuum degree higher than 133 Pa, for example, 10⁻² Pa, 10⁻³ Pa, or 10⁻⁴ Pa; a vacuum heat treatment temperature of 60-600° C., for example, 60° C., 80° C., 100° C., 150° C., 200° C., 300° C., 400° C., 500° C., 600° C., or any value between any two above-mentioned numerical values, and preferably 60-500° C.; or a vacuum heat treatment time of 3-30 minutes, for example, 3 minutes, 5 minutes, 10 minutes, 15 minutes, 20 minutes, 25 minutes, 30 minutes, or any value between any two above-mentioned numerical values, and preferably 5-20 minutes.

In a preferred embodiment method, cooling is performed after the vacuum heat treatment in step (2); and the cooling method is preferably air cooling or quenching. In the present disclosure, after the vacuum heat treatment described in step (2), the current collector intermediate is cooled, and the cooling operation method can be air cooling or quenching.

Air cooling refers to naturally cooling in the air. Gas cooling can be used for quenching, that is, cooling by compressed air or liquid nitrogen direct blowing, and the cooling speed is faster than air cooling. Quenching can maintain the crystalline state at the heat treatment temperature.

In a preferred embodiment method, when the upper conductive metal film and the lower conductive metal film in the current collector intermediate are each independently an aluminum film, the operating conditions of the vacuum heat treatment include: a vacuum degree higher than 133 Pa, for example, 10⁻² Pa, 10⁻³ Pa, or 10⁻⁴ Pa; a vacuum heat treatment temperature is 60-400° C., for example, 60° C., 80° C., 100° C., 200° C., 300° C., 400° C., or any value between any two above-mentioned numerical values; and a vacuum heat treatment time of 3-30 minutes, for example, 3 minutes, 5 minutes, 10 minutes, 15 minutes, 20 minutes, 25 minutes, 30 minutes, or any value between any two above-mentioned numerical values, and preferably 5-20 minutes.

In a preferred embodiment method, when the upper conductive metal film and the lower conductive metal film are each independently a copper film, the operating conditions of the vacuum heat treatment include: a vacuum degree higher than 133 Pa, for example, 10⁻² Pa, 10⁻³ Pa, or 10⁻⁴ Pa; a vacuum heat treatment temperature is 100-600° C., for example, 100° C., 120° C., 140° C., 200° C., 300° C., 400° C., 500° C., 600° C., or any value between any two above-mentioned numerical values, and preferably 100-500° C.; and a vacuum heat treatment time of 3-30 minutes, for example, 3 minutes, 5 minutes, 10 minutes, 15 minutes, 20 minutes, 25 minutes, 30 minutes, or any value between any two above-mentioned numerical values, and preferably 5-20 minutes.

In the present disclosure, since copper and aluminum have different melting points and different recrystallization temperatures, the temperature of heat treatment needs to be determined based on their recrystallization temperatures.

In the present disclosure, the upper conductive metal layer deposited on the upper surface of the polymer film and the lower conductive metal layer deposited on the lower surface of the polymer film are subjected to vacuum heat treatment, which can mitigate the lattice defects of the conductive metal film, release the residual stress generated by the conductive metal during deposition, induce the growth of conductive metal grains, reduce the scattering effect of grain boundaries on free electrons, and effectively improve the conductivity of the current collector.

In a preferred embodiment method, the above-mentioned preparation method further includes the following steps: a method for preparing the composite current collector, coating the adhesive according to the present disclosure on a substrate, and then depositing primer layers and/or conductive layers.

In the present disclosure, after the adhesive is applied to the substrate, under the coating conditions, the solvent gradually evaporates, and the main adhesive and the auxiliary adhesive form bonding layers on the substrate by in-situ polymerization reaction. To further ensure the coating effect, drying can be performed after the coating is completed.

In a preferred embodiment method, the preparation method includes the following steps:
(1) applying the adhesive described in the first aspect of the present disclosure to the upper surface and the lower surface of the substrate, to obtain a first intermediate having a structure of upper bonding layer-substrate-lower bonding layer; and
(2) preparing an upper conductive layer on the upper bonding layer, and preparing a lower conductive layer on the lower bonding layer, to obtain a composite current collector having a structure of upper conductive layer-upper bonding layer-substrate-lower bonding layer-lower conductive layer.

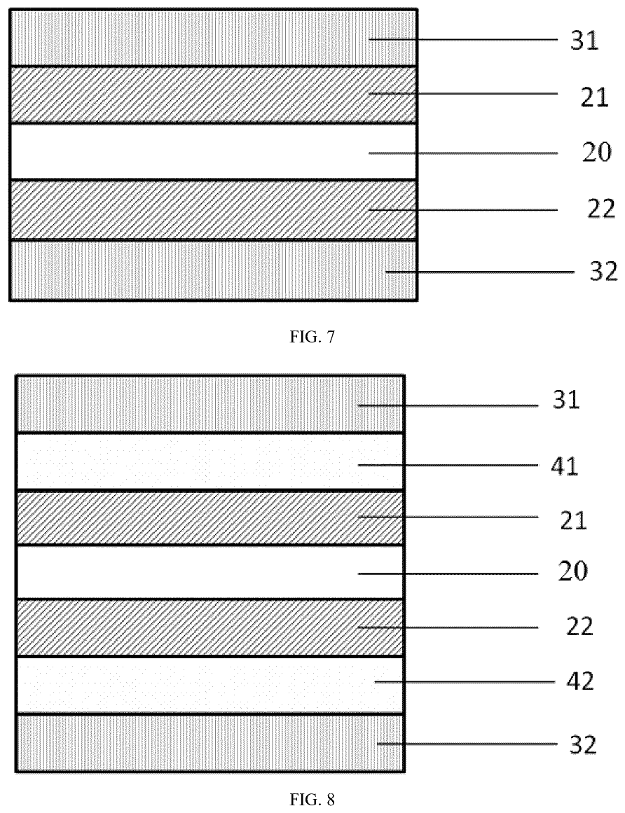

Specifically, in the present disclosure, the structure of upper bonding layer-substrate-lower bonding layer refers to that the first intermediate is composed of an upper bonding layer, a substrate, and a lower bonding layer in sequence. The structure of upper conductive layer-upper bonding layer-substrate-lower bonding layer-lower conductive layer refers to that the composite current collector is composed of an upper conductive layer 31, an upper bonding layer 21, a substrate 20, a lower bonding layer 22, and a lower conductive layer 32 in sequence, as shown in FIG. 7.

In a preferred embodiment method, the preparation method includes the following steps:
(1) applying the adhesive described in the first aspect of the present disclosure to the upper surface and the lower surface of the substrate, to obtain a first intermediate having a structure of upper bonding layer-substrate-lower bonding layer;
(2) preparing an upper primer layer on the upper bonding layer, and preparing a lower primer layer on the lower bonding layer, to obtain a second intermediate having a structure of upper primer layer-upper bonding layer-substrate-lower bonding layer-lower primer layer; and
(3) preparing an upper conductive layer on the upper primer layer, and preparing a lower conductive layer on the lower primer layer, to obtain a composite current collector having a structure of upper conductive layer-upper primer layer-upper bonding layer-substrate-lower bonding layer-lower primer layer-lower conductive layer.

Specifically, in the present disclosure, the structure of upper bonding layer-substrate-lower bonding layer refers to that the first intermediate is composed of an upper bonding layer, a substrate, and a lower bonding layer in sequence. The structure of upper primer layer-upper bonding layer-substrate-lower bonding layer-lower primer layer refers to that the second intermediate body is composed of an upper primer layer, an upper bonding layer, a substrate, a lower bonding layer and a lower primer layer in sequence. The structure of upper conductive layer-upper primer layer-upper bonding layer-substrate-lower bonding layer-lower primer layer-lower conductive layer refers to that the composite current collector is composed of an upper conductive layer 31, an upper primer layer 41, an upper bonding layer 21, a substrate 20, a lower bonding layer 22, a lower primer layer 42, and a lower conductive layer 32 in sequence, as shown in FIG. 8.

Specifically, the present disclosure does not make special restrictions on the specific preparation conditions of the composite current collector, and the preparation can be carried out according to conventional operations in this field. Primer layers and conductive layers can be prepared by evaporation, sputtering and in-situ reaction.

In a third aspect, the present disclosure provides an application of the current collector described in the first aspect of the present disclosure or the current collector prepared by the method described in the second aspect of the present disclosure in lithium-ion batteries.

The current collector according to the present disclosure is featured by high conductivity, high strength, high flexibility, light weight and ultra-thin thickness.

Polymer materials are lighter and more cost-effective than metal foils. Under the same area and thickness, the mass of the current collector according to the present disclosure is 59.04% lighter than that of copper foil, thereby reducing the weight of the battery. As the weight proportion of the composite current collector decreases, the energy density of the battery is increased by 5-10%.

In addition, the cost of high molecular polymers is lower than those of copper and aluminum foils, and the current collector prepared by the method according to the present disclosure has improved conductivity compared to conventional current collectors. As the conductivity is improved, the thickness of the metal layer can be thinner (<1,000 nm), to save more copper and aluminum, and cut down the cost.

Batteries prepared from the current collector according to the present disclosure have better safety performance compared with batteries prepared from traditional copper-aluminum foil current collectors. When a battery is short-circuited, a conductive layer is cracked and peeled off at the short-circuiting point, or melts instantly under the action of a large short-circuit current, which can cut off the short-circuit current loop within milliseconds; and the polymer layer is heated and melts on the short-circuit surface to form local collapses of the current collector structure, to cut off the short-circuit current loop before thermal runaway, thereby improving the safety of the battery.

Therefore, lithium-ion batteries prepared from the current collector according to the present disclosure are featured by light weight, low cost, and high energy density.

The technical solutions in embodiments of the present disclosure will be clearly and completely described below with reference to the drawings in embodiments of the present disclosure. Obviously, the embodiments described are only a part of, not all, the embodiments of the present disclosure. Based on the embodiments described herein, all other embodiments obtained by those of ordinary skill in the art without creative work are within the scope of protection of the present disclosure.

Unless otherwise specified, the reagents involved in the embodiments of the present disclosure are all commercially available products and can be purchased through commercial channels.

Some embodiments and comparative examples are listed below.
Thickness: Refer to GB/T 11378-2005 Metallic Coatings—Measurement of Coating Thickness—Profilometric Method.
Surface density: Refer to GB/T 22638.10-2016 Test Methods for Aluminium and Aluminium Alloy Foils—Part 10: Determination of Mass per Unit Area (Surface Density) of Coatings.
Sheet resistance/resistivity: Refer to ASTM F390 Standard Test Method for Sheet Resistance of Thin Metallic Films With a Collinear Four-Probe Array.
Bonding forces: Refer to GB/T 2792-2014 Measurement of Peel Adhesion Properties for Adhesive Tapes.

### EMBODIMENTS OF COMPOSITE CURRENT COLLECTORS WITH NO BONDING LAYER

### Embodiment 1

The substrate is PET, with a thickness of 6 μm; the evaporation source metal is Al, with the purity of Al higher than or equal to 3N; the vacuum degree is 10⁻⁴ Pa, the evaporation rate is 5 A/s, and one-time deposition is adopted, to form 100 nm Al metal layers on the upper and lower surfaces of the PET substrate respectively; and the Al composite current collector after film formation is subjected to vacuum heat treatment for 5 minutes at a vacuum degree of 10⁻³ Pa and a temperature of 80° C.

According to test results, the bonding force, surface density, sheet resistance, and resistivity of the aluminum composite current collector are shown in Table 1.

### Embodiment 2

The substrate is PET, with a thickness of 6 μm; the evaporation source metal is Al, with the purity of Al higher than or equal to 3N; the vacuum degree is 10⁻⁴ Pa, the evaporation rate is 5 A/s, and one-time deposition is adopted, to form 1,000 nm Al metal layers on the upper and lower surfaces of the PET substrate respectively; and the Al composite current collector after film formation is subjected to vacuum heat treatment for 5 minutes at a vacuum degree of 10⁻³ Pa and a temperature of 80° C.

According to test results, the bonding force, surface density, sheet resistance, and resistivity of the aluminum composite current collector are shown in Table 1.

FIG. 2 is a cross-sectional TEM image of the aluminum composite current collector obtained in Embodiment 2. According to FIG. 2, grain sizes are in the range of 100-300 nm, there are a large number of linear defects in the grains, and the conductivity is higher than that of bulk Al.

### Embodiment 3

The substrate is PET, with a thickness of 6 μm; the evaporation source metal is Al, with the purity of Al higher than or equal to 3N; the vacuum degree is 10⁻⁴ Pa, the evaporation rate is 5 A/s, and one-time deposition is adopted, to form 1,000 nm Al metal layers on the upper and lower surfaces of the PET substrate respectively; and the Al composite current collector after film formation is subjected to vacuum heat treatment for 5 minutes at a vacuum degree of 10⁻³ Pa and a temperature of 120° C.

According to test results, the bonding force, surface density, sheet resistance, and resistivity of the aluminum composite current collector are shown in Table 1.

### Embodiment 4

The substrate is PET, with a thickness of 6 μm; the evaporation source metal is Al, with the purity of Al higher than or equal to 3N; the vacuum degree is 10⁻⁴ Pa, the evaporation rate is 5 A/s, and one-time deposition is adopted, to form 1,000 nm Al metal layers on the upper and lower surfaces of the PET substrate respectively; and the Al composite current collector after film formation is subjected to vacuum heat treatment for 5 minutes at a vacuum degree of 10⁻³ Pa and a temperature of 180° C.

According to test results, the bonding force, surface density, sheet resistance, and resistivity of the aluminum composite current collector are shown in Table 1.

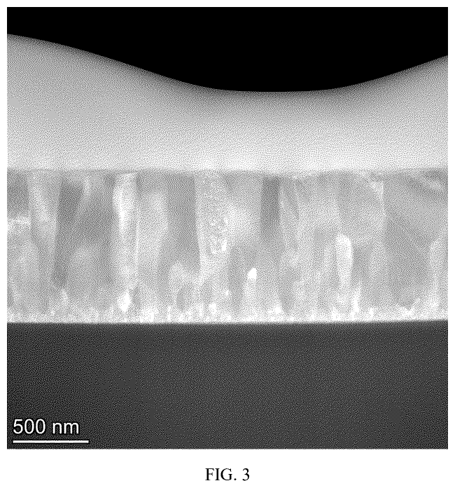

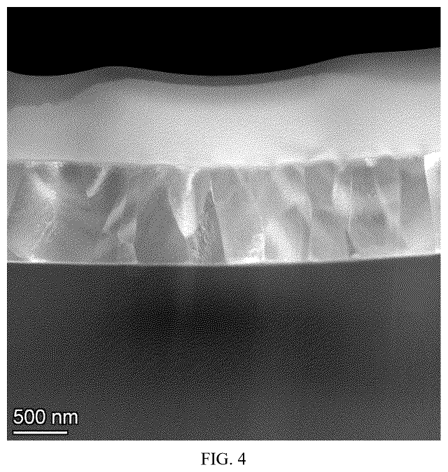

FIGS. 3 and 4 are TEM images of the aluminum composite current collector of Embodiment 4 before and after heat treatment, showing the cross-sectional structures of the aluminum composite current collector before and after heat treatment respectively. According to FIGS. 3 and 4, grain sizes are in the range of 30-100 nm before heat treatment, and 300-500 nm after heat treatment. The grains grow larger, the grain arrangement is more uniform, the number of defects is less, and the conductivity is enhanced.

### Comparative Example 1

The aluminum composite current collector is prepared according to the method of Embodiment 1, except that the Al composite current collector after film formation is not subjected to vacuum heat treatment.

According to test results, the bonding force, surface density, sheet resistance, and resistivity of the aluminum composite current collector are shown in Table 1.

### Comparative Example 2

The aluminum composite current collector is prepared according to the method of Embodiment 2, except that the Al composite current collector after film formation is not subjected to vacuum heat treatment.

According to test results, the bonding force, surface density, sheet resistance, and resistivity of the aluminum composite current collector are shown in Table 1.

### Embodiment 5

The substrate is PI, with a thickness of 7.5 μm; the evaporation source metal is Al, with the purity of Al higher than or equal to 3N; the vacuum degree is 10⁻⁴ Pa, the evaporation rate is 5 A/s, and one-time deposition is adopted, to form 100 nm Al metal layers on the upper and lower surfaces of the PI substrate respectively; and the Al composite current collector after film formation is subjected to vacuum heat treatment for 5 minutes at a vacuum degree of 10⁻³ Pa, and a temperature of 150° C.

According to test results, the bonding force, surface density, sheet resistance, and resistivity of the aluminum composite current collector are shown in Table 1.

### Embodiment 6

The substrate is PI, with a thickness of 7.5 μm; the evaporation source metal is Al, with the purity of Al higher than or equal to 3N; the vacuum degree is 10⁻⁴ Pa, the evaporation rate is 5 A/s, and one-time deposition is adopted, to form 1,000 nm Al metal layers on the upper and lower surfaces of the PI substrate respectively; and the Al composite current collector after film formation is subjected to vacuum heat treatment for 5 minutes at a vacuum degree of 10⁻³ Pa, and a temperature of 150° C.

According to test results, the bonding force, surface density, sheet resistance, and resistivity of the aluminum composite current collector are shown in Table 1.

### Embodiment 7

The substrate is PI, with a thickness of 7.5 μm; the evaporation source metal is Al, with the purity of Al higher than or equal to 3N; the vacuum degree is 10⁻⁴ Pa, the evaporation rate is 5 A/s, and one-time deposition is adopted, to form 1,000 nm Al metal layers on the upper and lower surfaces of the PI substrate respectively; and the Al composite current collector after film formation is subjected to vacuum heat treatment for 5 minutes at a vacuum degree of 10⁻³ Pa, and a temperature of 300° C.

According to test results, the bonding force, surface density, sheet resistance, and resistivity of the aluminum composite current collector are shown in Table 1.

### Comparative Example 3

The aluminum composite current collector is prepared according to the method of Embodiment 5, except that the Al composite current collector after film formation is not subjected to vacuum heat treatment.

According to test results, the bonding force, surface density, sheet resistance, and resistivity of the aluminum composite current collector are shown in Table 1.

### Comparative Example 4

The aluminum composite current collector is prepared according to the method of Embodiment 6, except that the Al composite current collector after film formation is not subjected to vacuum heat treatment.

According to test results, the bonding force, surface density, sheet resistance, and resistivity of the aluminum composite current collector are shown in Table 1.

TABLE 1

| | Sheet | | Bonding | Surface |
|---|---|---|---|---|
| | Resistance | Resistivity | Force | Density |
| No. | (mΩ/□) | (μΩ · cm) | (N/15 mm) | (g/m²) |
| Embodiment 1 | 323.56 | 4.48 | 1.85 | 9.78 |
| Embodiment 2 | 37.46 | 3.64 | 5.32 | 13.01 |
| Embodiment 3 | 33.29 | 3.25 | 5.93 | 13.43 |
| Embodiment 4 | 30.85 | 3.03 | 7.31 | 13.88 |
| Comparative | 791.84 | 10.75 | 0.26 | 9.09 |
| Example 1 | | | | |
| Comparative | 41.93 | 4.28 | 2.25 | 12.61 |
| Example 2 | | | | |
| Embodiment 5 | 318.93 | 4.27 | 2.78 | 10.84 |
| Embodiment 6 | 31.25 | 3.11 | 4.36 | 15.16 |
| Embodiment 7 | 29.05 | 2.91 | 5.25 | 15.76 |
| Comparative | 755.74 | 9.88 | 0.31 | 10.56 |
| Example 3 | | | | |
| Comparative | 48.72 | 4.75 | 0.45 | 14.89 |
| Example 4 | | | | |

According to the data in Table 1, when a comparison is made between Embodiment 1 and Comparative Example 1, vacuum heat treatment reduces the sheet resistance and resistivity of the material structure, improves the bonding force, and increases the surface density of the material; and similarly, when comparisons are made between Embodiment 2 and Comparative Example 2, between Embodiment 5 and Comparative Example 3, and between Embodiment 6 and Comparative Example 4, vacuum heat treatment also improves the conductivity, bonding force, and surface density of the material.

### Embodiment 8

The substrate is PET, with a thickness of 6 μm; the evaporation source metal is Cu, with the purity of Cu higher than or equal to 3N; the vacuum degree is 10⁻⁴ Pa, the evaporation rate is 5 A/s, and one-time deposition is adopted, to form 100 nm Cu metal layers on the upper and lower surfaces of the PET substrate respectively; and the Cu composite current collector after film formation is subjected to vacuum heat treatment for 5 minutes at a vacuum degree of 10⁻³ Pa and a temperature of 100° C.

According to test results, the bonding force, surface density, sheet resistance, and resistivity of the copper composite current collector are shown in Table 2.

### Embodiment 9

The substrate is PET, with a thickness of 6 μm; the evaporation source metal is Cu, with the purity of Cu higher than or equal to 3N; the vacuum degree is 10⁻⁴ Pa, the evaporation rate is 5 A/s, and one-time deposition is adopted, to form 1,000 nm Cu metal layers on the upper and lower surfaces of the PET substrate respectively; and the Cu composite current collector after film formation is subjected to vacuum heat treatment for 5 minutes at a vacuum degree of 10⁻³ Pa and a temperature of 100° C.

According to test results, the bonding force, surface density, sheet resistance, and resistivity of the copper composite current collector are shown in Table 2.

FIG. 5 is a cross-sectional TEM image of the copper composite current collector obtained in Embodiment 9. According to FIG. 5, grain sizes of copper metal are in the range of 100-400 nm, the grain boundaries are clear, the internal orientation of the grains tends to be uniform, and the conductivity is good.

### Embodiment 10

The substrate is PET, with a thickness of 6 μm; the evaporation source metal is Cu, with the purity of Cu higher than or equal to 3N; the vacuum degree is 10⁻⁴ Pa, the evaporation rate is 5 A/s, and one-time deposition is adopted, to form 1,000 nm Cu metal layers on the upper and lower surfaces of the PET substrate respectively; and the Cu composite current collector after film formation is subjected to vacuum heat treatment for 5 minutes at a vacuum degree of 10⁻³ Pa and a temperature of 150° C.

According to test results, the bonding force, surface density, sheet resistance, and resistivity of the copper composite current collector are shown in Table 2.

### Embodiment 11

The substrate is PET, with a thickness of 6 μm; the evaporation source metal is Cu, with the purity of Cu higher than or equal to 3N; the vacuum degree is 10⁻⁴ Pa, the evaporation rate is 5 A/s, and one-time deposition is adopted, to form 1,000 nm Cu metal layers on the upper and lower surfaces of the PET substrate respectively; and the Cu composite current collector after film formation is subjected to vacuum heat treatment for 5 minutes at a vacuum degree of 10⁻³ Pa and a temperature of 180° C.

According to test results, the bonding force, surface density, sheet resistance, and resistivity of the copper composite current collector are shown in Table 2.

### Comparative Example 5

The copper composite current collector is prepared according to the method of Embodiment 8, except that the Cu composite current collector after film formation is not subjected to vacuum heat treatment.

According to test results, the bonding force, surface density, sheet resistance, and resistivity of the copper composite current collector are shown in Table 2.

### Comparative Example 6

The copper composite current collector is prepared according to the method of Embodiment 9, except that the Cu composite current collector after film formation is not subjected to vacuum heat treatment.

According to test results, the bonding force, surface density, sheet resistance, and resistivity of the copper composite current collector are shown in Table 2.

### Embodiment 12

The substrate is PI, with a thickness of 7.5 μm; the evaporation source metal is Cu, with the purity of Cu higher than or equal to 3N; the vacuum degree is 10⁻⁴ Pa, the evaporation rate is 5 A/s, and one-time deposition is adopted, to form 100 nm Cu metal layers on the upper and lower surfaces of the PI substrate respectively; and the Cu composite current collector after film formation is subjected to vacuum heat treatment for 5 minutes at a vacuum degree of 10⁻³ Pa, and a temperature of 100° C.

According to test results, the bonding force, surface density, sheet resistance, and resistivity of the copper composite current collector are shown in Table 2.

### Embodiment 13

The substrate is PI, with a thickness of 7.5 μm; the evaporation source metal is Cu, with the purity of Cu higher than or equal to 3N; the vacuum degree is 10⁻⁴ Pa, the evaporation rate is 5 A/s, and one-time deposition is adopted, to form 800 nm Cu metal layers on the upper and lower surfaces of the PI substrate respectively; and the Cu composite current collector after film formation is subjected to vacuum heat treatment for 5 minutes at a vacuum degree of 10⁻³ Pa, and a temperature of 100° C.

According to test results, the bonding force, surface density, sheet resistance, and resistivity of the copper composite current collector are shown in Table 2.

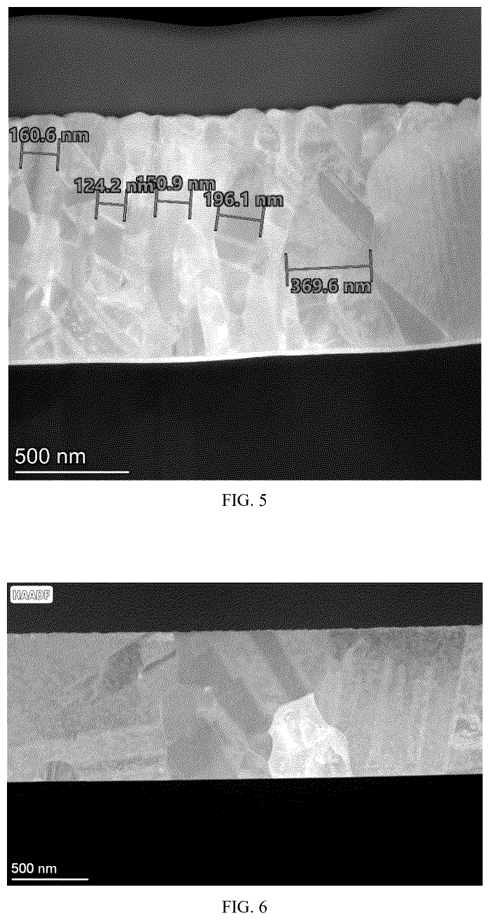

FIG. 6 is a cross-sectional TEM image of the copper composite current collector obtained in Embodiment 13. According to FIG. 6, after vacuum heat treatment, the grain size of copper metal is 239.8 nm, the resistivity is 1.74 μΩ·cm, and the conductivity is close to that of bulk Cu.

### Embodiment 14

The substrate is PI, with a thickness of 7.5 μm; the evaporation source metal is Cu, with the purity of Cu higher than or equal to 3N; the vacuum degree is 10⁻⁴ Pa, the evaporation rate is 5 A/s, and one-time deposition is adopted, to form 800 nm Cu metal layers on the upper and lower surfaces of the PI substrate respectively; and the Cu composite current collector after film formation is subjected to vacuum heat treatment for 5 minutes at a vacuum degree of 10⁻³ Pa, and a temperature of 200° C.

According to test results, the bonding force, surface density, sheet resistance, and resistivity of the copper composite current collector are shown in Table 2.

### Embodiment 15

The substrate is PI, with a thickness of 7.5 μm; the evaporation source metal is Cu, with the purity of Cu higher than or equal to 3N; the vacuum degree is 10⁻⁴ Pa, the evaporation rate is 5 A/s, and one-time deposition is adopted, to form 800 nm Cu metal layers on the upper and lower surfaces of the PI substrate respectively; and the Cu composite current collector after film formation is subjected to vacuum heat treatment for 5 minutes at a vacuum degree of 10⁻³ Pa, and a temperature of 400° C.

According to test results, the bonding force, surface density, sheet resistance, and resistivity of the copper composite current collector are shown in Table 2.

### Comparative Example 7

The copper composite current collector is prepared according to the method of Embodiment 12, except that the Cu composite current collector after film formation is not subjected to vacuum heat treatment.

According to test results, the bonding force, surface density, sheet resistance, and resistivity of the copper composite current collector are shown in Table 2.

### Comparative Example 8

The copper composite current collector is prepared according to the method of Embodiment 13, except that the Cu composite current collector after film formation is not subjected to vacuum heat treatment.

According to test results, the bonding force, surface density, sheet resistance, and resistivity of the copper composite current collector are shown in Table 2.

TABLE 2

| | Sheet | | Bonding | Surface |
|---|---|---|---|---|
| | Resistance | Resistivity | Force | Density |
| No. | (mΩ/□) | (μΩ · cm) | (N/15 mm) | (g/m²) |
| Embodiment 8 | 162.16 | 2.55 | 1.68 | 10.21 |
| Embodiment 9 | 19.63 | 1.98 | 2.54 | 23.01 |
| Embodiment 10 | 19.50 | 1.93 | 4.07 | 23.85 |
| Embodiment 11 | 18.79 | 1.77 | 6.74 | 24.26 |
| Comparative | 198.55 | 2.74 | 0.18 | 9.89 |
| Example 5 | | | | |
| Comparative | 21.00 | 2.07 | 0.49 | 21.88 |
| Example 6 | | | | |
| Embodiment 12 | 154.49 | 2.41 | 1.47 | 12.55 |
| Embodiment 13 | 21.75 | 1.74 | 2.63 | 25.99 |
| Embodiment 14 | 21.25 | 1.70 | 3.71 | 26.87 |
| Embodiment 15 | 21.00 | 1.68 | 6.04 | 27.36 |
| Comparative | 188.35 | 2.63 | 0.22 | 11.96 |
| Example 7 | | | | |
| Comparative | 26.46 | 2.08 | 0.46 | 25.12 |
| Example 8 | | | | |

According to the data in Table 2, when a comparison is made between Embodiment 8 and Comparative Example 5, heat treatment reduces the sheet resistance and resistivity of the material structure, improves the bonding force, and increases the surface density of the material; and similarly, when comparisons are made between Embodiment 9 and Comparative Example 6, between Embodiment 12 and Comparative Example 7, and between Embodiment 13 and Comparative Example 8, heat treatment also improves the conductivity, bonding force, and surface density of the material.

According to the data in Tables 1 and 2, the upper conductive metal layer deposited on the upper surface of the polymer film and the lower conductive metal layer deposited on the lower surface of the polymer film are subjected to vacuum heat treatment, which can mitigate the lattice defects of the conductive metal film, release the residual stress generated by the conductive metal during deposition, induce the growth of conductive metal grains, reduce the scattering effect of grain boundaries on free electrons, and effectively improve the conductivity of the current collector.

### EMBODIMENTS OF COMPOSITE CURRENT COLLECTORS WITH BONDING LAYERS

Specifically, the liquid epoxy resin was purchased from Henan Shuizhihuan Industrial Co., Ltd., and the product designation is NPEL128.

### Embodiment 1

(1) Use a microgravure coating machine to coat an adhesive on the upper and lower surfaces of a 6 μm thick polyethylene terephthalate film at a travel speed of 0.5 m/min, a winding tension of 16 N, an unwinding tension of 14 N, and an oven temperature of 80° C., to obtain a first intermediate having the structure of upper bonding layer-substrate-lower bonding layer; and
specifically, the adhesive is a mixture of methylene succinic acid, glyoxal, epoxy resin, and anhydrous ethanol, including 1.5 wt % methylene succinic acid, 1.5 wt % glyoxal, and 0.03 wt % epoxy resin, and the upper and lower bonding layers are the same, with a thickness of 0.2 μm;
(2) evaporate a nickel-chromium alloy layer on the upper and lower surfaces of the first intermediate respectively, to obtain a second intermediate having the structure of upper primer layer-upper bonding layer-substrate-lower bonding layer-lower primer layer; specifically, the upper and lower primer layers are the same, with a thickness of 0.01 μm, and the mass ratio of nickel to chromium in the nickel-chromium alloy is 3:1; and
(3) evaporate a copper layer on the upper and lower surfaces of the second intermediate body respectively, to obtain a composite current collector having the structure of upper conductive layer-upper primer layer-upper bonding layer-substrate-lower bonding layer-lower primer layer-lower conductive layer; specifically the upper and lower conductive layers are the same, with a thickness of 1 μm.

### Embodiment 2

(1) Use a microgravure coating machine to coat an adhesive on the upper and lower surfaces of a 6 μm thick polyethylene terephthalate film at a travel speed of 0.5 m/min, a winding tension of 16 N, an unwinding tension of 14 N, and an oven temperature of 80° C., to obtain a first intermediate having the structure of upper bonding layer-substrate-lower bonding layer; and
specifically, the adhesive is a mixture of methylene succinic acid, thioglycolic acid, styrene, and anhydrous ethanol, including 2 wt % methylene succinic acid, 2 wt % thioglycolic acid, and 0.08 wt % styrene, and the upper and lower bonding layers are the same, with a thickness of 0.3 μm;
(2) evaporate a nickel-chromium alloy layer on the upper and lower surfaces of the first intermediate respectively, to obtain a second intermediate having the structure of upper primer layer-upper bonding layer-substrate-lower bonding layer-lower primer layer; specifically, the upper and lower primer layers are the same, with a thickness of 0.02 μm, and the mass ratio of nickel to chromium in the nickel-chromium alloy is 3:1; and
(3) evaporate a copper layer on the upper and lower surfaces of the second intermediate body respectively, to obtain a composite current collector having the structure of upper conductive layer-upper primer layer-upper bonding layer-substrate-lower bonding layer-lower primer layer-lower conductive layer; specifically the upper and lower conductive layers are the same, with a thickness of 1 μm.

### Embodiment 3

(1) Use a microgravure coating machine to coat an adhesive on the upper and lower surfaces of a 6 μm thick polyethylene terephthalate film at a travel speed of 0.5 m/min, a winding tension of 16 N, an unwinding tension of 14 N, and an oven temperature of 80° C., to obtain a first intermediate having the structure of upper bonding layer-substrate-lower bonding layer; and
specifically, the adhesive is a mixture of methylene succinic acid, styrene, and anhydrous ethanol, including 1 wt % methylene succinic acid, and 0.03 wt % styrene, and the upper and lower bonding layers are the same, with a thickness of 0.4 μm;
(2) evaporate a nickel-chromium alloy layer on the upper and lower surfaces of the first intermediate respectively, to obtain a second intermediate having the structure of upper primer layer-upper bonding layer-substrate-lower bonding layer-lower primer layer; specifically, the upper and lower primer layers are the same, with a thickness of 0.04 μm, and the mass ratio of nickel to chromium in the nickel-chromium alloy is 3:1; and
(3) evaporate a copper layer on the upper and lower surfaces of the second intermediate body respectively, to obtain a composite current collector having the structure of upper conductive layer-upper primer layer-upper bonding layer-substrate-lower bonding layer-lower primer layer-lower conductive layer; specifically the upper and lower conductive layers are the same, with a thickness of 1 μm.

### Embodiment 4

(1) Use a microgravure coating machine to coat an adhesive on the upper and lower surfaces of a 4.5 μm thick polyethylene terephthalate film at a travel speed of 0.5 m/min, a winding tension of 16 N, an unwinding tension of 14 N, and an oven temperature of 80° C., to obtain a first intermediate having the structure of upper bonding layer-substrate-lower bonding layer; and
specifically, the adhesive is a mixture of maleic acid, isocyanate, and anhydrous ethanol, including 6 wt % maleic acid, and 0.36 wt % isocyanate, and the upper and lower bonding layers are the same, with a thickness of 0.6 μm;
(2) evaporate a nickel alloy layer on the upper and lower surfaces of the first intermediate respectively, to obtain a second intermediate having the structure of upper primer layer-upper bonding layer-substrate-lower bonding layer-lower primer layer; specifically, the upper and lower primer layers are the same, with a thickness of 0.05 μm; and
(3) evaporate a copper layer on the upper and lower surfaces of the second intermediate body respectively, to obtain a composite current collector having the structure of upper conductive layer-upper primer layer-upper bonding layer-substrate-lower bonding layer-lower primer layer-lower conductive layer; specifically the upper and lower conductive layers are the same, with a thickness of 1 μm.

### Embodiment 5

(1) Use a microgravure coating machine to coat an adhesive on the upper and lower surfaces of an 8 μm thick polyethylene terephthalate film at a travel speed of 0.5 m/min, a winding tension of 16 N, an unwinding tension of 14 N, and an oven temperature of 80° C., to obtain a first intermediate having the structure of upper bonding layer-substrate-lower bonding layer; and
specifically, the adhesive is a mixture of guanidinoacetic acid, methyl acrylate, and anhydrous ethanol, including 8 wt % guanidinoacetic acid, and 0.04 wt % methyl acrylate, and the upper and lower bonding layers are the same, with a thickness of 0.8 μm;
(2) evaporate an aluminum oxide layer on the upper and lower surfaces of the first intermediate respectively, to obtain a second intermediate having the structure of upper primer layer-upper bonding layer-substrate-lower bonding layer-lower primer layer; specifically, the upper and lower primer layers are the same, with a thickness of 0.06 μm; and
(3) evaporate a copper layer on the upper and lower surfaces of the second intermediate body respectively, to obtain a composite current collector having the structure of upper conductive layer-upper primer layer-upper bonding layer-substrate-lower bonding layer-lower primer layer-lower conductive layer; specifically the upper and lower conductive layers are the same, with a thickness of 1 μm.

### Embodiment 6

Same as Embodiment 1, except that conductive layers are made of aluminum, and primer layers are made of aluminum oxide.

### Comparative Example 1

Compared with Embodiment 1, the difference is that bonding layers are omitted.

### Comparative Example 2

Compared with Embodiment 1, the difference is that the adhesive is epoxy resin glue, purchased from Shenzhen Xinruizhong Science & Technology Co., Ltd., and the product designation is LB-3501AB.

### Comparative Example 3

Compared with Embodiment 5, the difference is that the adhesive is acrylic resin curing adhesive, purchased from Shenzhen Kunyang Technology Co., Ltd., and the product designation is 3M DP810NS.

### Test Example 1

The mechanical properties of the composite current collectors prepared in embodiments and comparative examples were characterized, and the results are shown in Table 1. The tensile strength of the composite current collector is tested in accordance with HG/T 2580-2008. MD represents the longitudinal tensile strength, in MVPa; and TD represents the transverse tensile strength, in MVPa.

Bonding forces between primer layers and the substrate are tested in accordance with GB/T 2792-2014. The bonding force between the upper primer layer and the substrate, and the bonding force between the lower primer layer and the substrate are tested respectively, and then the average value is taken.

TABLE 1

| | | Bonding Force Between |
|---|---|---|
| | Tensile Strength of | Primer Layers and |
| | Current Collector (MPa) | Substrate (N/15 mm) |
| Embodiment 1 | MD: 221.11 TD: 206.16 | 7.50 |
| Embodiment 2 | MD: 223.23 TD: 203.69 | 6.44 |
| Embodiment 3 | MD: 226.41 TD: 207.17 | 6.02 |
| Embodiment 4 | MD: 221.77 TD: 206.83 | 5.28 |
| Embodiment 5 | MD: 215.19 TD: 201.55 | 5.11 |
| Embodiment 6 | MD: 235.38 TD: 211.09 | 6.39 |
| Comparative | MD: 203.66 TD: 175.72 | 4.31 |
| Example 1 | | |
| Comparative | MD: 209.03 TD: 182.83 | 1.49 |
| Example 2 | | |
| Comparative | MD: 197.71 TD: 175.64 | 1.07 |
| Example 3 | | |

### Test Example 2

The current collectors prepared in embodiments and comparative examples were assembled into batteries, which then were tested for their performance parameters. The test results are shown in Table 2.

Specifically, the battery is assembled in the following steps:

Mix LiNi_{0.5}Co_{0.2}Mn_{0.3}O₂, polyvinylidene fluoride as the binder, and carbon black as the conductive agent in a weight ratio of 95:3:2; add N-methyl-2-pyrrolidone of a weight equal to 43% of the weight of the mixture into the mixture; stir and mix the mixture to obtain the cathode material slurry; evenly apply the cathode material slurry on both sides of the cathode current collector, with a coating weight of 205 g/m² on each side; and then dry, roll, die cut, and punching cut the cathode current collector to obtain the cathode sheet.

Mix graphite particles, styrene-butadiene rubber as the binder, sodium carboxymethyl cellulose, and carbon black as the conductive agent in a weight ratio of 95:2.5:1.5:1; add water of a weight equal to 82% of the weight of the mixture into the mixture; stir and mix the mixture to obtain the anode material slurry; evenly apply the anode material slurry on both sides of the anode current collector, with a coating weight of 100 g/m² on each side; and then dry, roll, die cut, and punching cut the anode current collector to obtain the anode sheet.

In an argon-filled glove box with both the water content and oxygen content below 5 ppm, wind the cathode sheet, the PP/PE/PP diaphragm and the anode sheet together into bare cells; place the bare cells in the battery case; inject the electrolyte (with EC:EMC equal to 3:7 by volume, and LiPF₆ content of 1 mol/L); and then carry out operations such as sealing and formation to obtain the lithium-ion secondary battery (hereinafter referred to as the battery).

Specifically, when any of the composite current collectors prepared in Embodiments 1 to 5 is used as the anode current collector, the cathode current collector in the battery is aluminum foil. When the composite current collector prepared in Embodiment 6 is used as the cathode current collector, the cathode current collector in the battery is copper foil.

Control the charge and discharge voltage range to 3-4.3 V; charge and discharge the battery at 0.2 C for three cycles at room temperature, and take the average value of the three cycles, to evaluate the battery's first discharge capacity, first charge and discharge efficiency and energy density.

Control the charge and discharge voltage range to 3-4.3 V; charge and discharge the battery at 0.2 C for three cycles at a constant temperature of 45° C., to obtain the standard capacity; then repeat the cycle of charging and discharging the battery at 1 C, and record the number of cycles when the capacity drops to 70% of the standard capacity.

TABLE 2

| | | First | | Number of |
|---|---|---|---|---|
| | First | Charge and | | Cycles to |
| | Discharge | Discharge | Energy | Reach 70% |
| | Capacity | Efficiency | Density | Capacity |
| No. | (mAh) | (%) | (mWh/kg) | Retention Rate |
| Embodiment 1 | 1330.12 | 93.05% | 177.35 | 1117 |
| Embodiment 2 | 1325.67 | 91.15% | 176.76 | 997 |
| Embodiment 3 | 1316.76 | 89.50% | 175.57 | 947 |
| Embodiment 4 | 1312.56 | 88.26% | 175.01 | 863 |
| Embodiment 5 | 1298.67 | 87.48% | 173.16 | 809 |
| Embodiment 6 | 1320.56 | 92.26% | 163.93 | 1106 |
| Comparative | 1219.78 | 85.80% | 162.64 | 751 |
| Example 1 | | | | |
| Comparative | 1201.73 | 84.77% | 160.23 | 743 |
| Example 2 | | | | |
| Comparative | 1194.44 | 84.05% | 159.54 | 739 |
| Example 3 | | | | |

The preferred embodiment methods of the present disclosure are described in detail above, but the present disclosure is not limited thereto. Within the scope of the technical conception of the present disclosure, the technical solution can be made into a variety of simple variations, including combining various technical features in any other suitable way. These simple variations and combinations should also be regarded as the content disclosed in the present disclosure and belong to the protection scope of the present disclosure.

What is claimed is:

1. A composite current collector, comprising an upper metal layer, a lower metal layer, and a polymer layer between the upper metal layer and the lower metal layer, wherein surface densities of the upper metal layer and the lower metal layer are each independently 0.5-30 g/m², and grain sizes of the metal respectively contained in the upper metal layer and the lower metal layer range from 50 nm to 5 μm; and the sheet resistance of the composite current collector is 5-5,000 mΩ/□, and the resistivity is 1-5 μΩ·cm.

2. The composite current collector according to claim 1, wherein the material of the polymer layer comprises one or more constituents selected from the group consisting of polyethylene, biaxially oriented polypropylene, polyethylene terephthalate, polyethylene naphthalate, poly(p-phenylene terephthalamide), polyimide, polycarbonate, polyetheretherketone, polyoxymethylene, poly(p-phenylene sulfide), poly(p-phenylene oxide), polyvinyl chloride, polyamide, and polytetrafluoroethylene, and preferably, the material of the polymer layer is selected from polyethylene terephthalate film, biaxially oriented polypropylene film, and polyimide film with a temperature resistance rating of greater than or equal to 400° C.

3. The composite current collector according to claim 1, wherein the upper metal layer and the lower metal layer are made of copper or aluminum.

4. The composite current collector according to claim 1, wherein the bonding force between the upper metal layer and the polymer layer and the bonding force between the lower metal layer and the polymer layer are 0.5-20 N/15 mm, respectively.

5. The composite current collector according to claim 1, wherein thicknesses of the upper metal layer and the lower metal layer are each independently 100-1,500 nm, and preferably 100-1,000 nm; and
preferably, the thickness of the polymer layer is 0.001-0.5 mm, and preferably 0.003-0.25 mm.

6. The composite current collector according to claim 1, further comprising bonding layers, wherein the bonding layers are attached to the two surfaces of the polymer layer, and the upper metal layer and the lower metal layer are respectively on the corresponding bonding layers and are arranged away from the polymer layer; and
each of the bonding layers is obtained by curing an adhesive comprising a main adhesive, a secondary adhesive, and a solvent, wherein the main adhesive comprises one or more constituents selected from the group consisting of maleic acid, methylene succinic acid, ethylene succinic acid, methylene adipic acid, guanidinoacetic acid, thioglycolic acid, acrylic acid, methacrylic acid, acrylamide, and glyoxal; and the secondary adhesive comprises one or more constituents selected from the group consisting of styrene, polystyrene, polyurethane, isocyanate, ethyl acrylate, styrene-butadiene rubber, phenolic resin, urea-formaldehyde resin, epoxy resin, and methyl acrylate.

7. The composite current collector according to claim 6, wherein the mass content of the main adhesive is 1% to 20% based on the total mass of the adhesive; the mass of the secondary adhesive is 0.5% to 15% of the mass of the main adhesive; and preferably, the solvent is water, and preferably deionized water.

8. The composite current collector according to claim 6, wherein the bonding layers comprise an upper bonding layer and a lower bonding layer, wherein the upper bonding layer is on an upper surface of the polymer layer and the lower bonding layer is on a lower surface of the polymer layer; preferably, the upper bonding layer and the lower bonding layer are respectively and independently obtained by curing the adhesive comprising a main adhesive, a secondary adhesive, and a solvent; and preferably, the upper bonding layer and the lower bonding layer are made of the same material and have the same thickness; and
the upper metal layer is on the upper bonding layer, and the lower metal layer is on the lower bonding layer; and preferably, the upper metal layer and the lower metal layer are made of the same material and have the same thickness.

9. The composite current collector according to claim 8, further comprising primer layers, wherein one of the primer layers is between the upper bonding layer and the upper metal layer, and the other one of the primer layers is between the lower bonding layer and the lower metal layer;
preferably, the material of the primer layer comprises one or more constituents selected from the group consisting of nickel, nickel-chromium alloy, and aluminum oxide;
preferably, the bonding layers comprise an upper bonding layer and a lower bonding layer, and there are two primer layers, comprising an upper primer layer and a lower primer layer; and the upper bonding layer is on the upper surface of the polymer layer, the lower bonding layer is on the lower surface of the polymer layer, the upper metal layer is on the upper bonding layer, the lower metal layer is on the lower bonding layer, the upper primer layer is between the upper bonding layer and the upper metal layer, and the lower primer layer is between the lower bonding layer and the lower metal layer;
preferably, the material of the upper primer layer and the material of the lower primer layer respectively and independently comprise one or more constituents selected from the group consisting of nickel, nickel-chromium alloy, and aluminum oxide; and
preferably, the upper primer layer and the lower primer layer are made of the same material and have the same thickness.

10. A method for preparing the composite current collector according to claim 1, comprising the following steps:
(1) using a conductive metal source as a deposition raw material, depositing an upper conductive metal film on the upper surface of the polymer layer, and depositing a lower conductive metal film on the lower surface of the polymer layer, to obtain a current collector intermediate; and
(2) performing a vacuum heat treatment to the current collector intermediate to modify the upper conductive metal film and the lower conductive metal film, to obtain a current collector comprising an upper metal layer, a polymer layer, and a lower metal layer in sequence.

11. The preparation method according to claim 10, wherein the conductive metal source is made of copper wires with a purity higher than or equal to 3N or aluminum wires with a purity higher than or equal to 3N.

12. The preparation method according to claim 10, wherein the depositing described in step (1) is carried out by using a method selected from vacuum evaporation coating, vacuum sputtering coating, vacuum ion coating, and vacuum chemical vapor deposition coating, and preferably vacuum evaporation coating;
preferably, the vacuum evaporation coating comprises: turning on the evaporation source current, heating the conductive metal source, and depositing an upper conductive metal film and a lower conductive metal film on the surface of the polymer layer; and
preferably, the operating conditions of the vacuum evaporation coating comprise: a vacuum degree higher than 10⁻³ Pa; a cold roller temperature of −25° C. to 35° C.; an evaporation source (ES) distance of greater than or equal to 50 mm, and preferably 50-500 mm; and an evaporation temperature of higher than or equal to 800° C., and preferably 800-2,000° C.

13. The preparation method according to claim 10, wherein the operating conditions of the vacuum heat treatment described in step (2) comprise: a vacuum degree higher than 133 Pa, a vacuum heat treatment temperature of 60-600° C., and preferably 60-500° C.; and a vacuum heat treatment time of 3-30 minutes, and preferably 5-20 minutes; and
preferably, cooling is performed after the vacuum heat treatment in step (2); and the cooling method is preferably air cooling or quenching.

14. The preparation method according to claim 10, wherein when the upper conductive metal film and the lower conductive metal film are each independently an aluminum film, the operating conditions of the vacuum heat treatment comprise: a vacuum degree higher than 133 Pa, a vacuum heat treatment temperature of 60-400° C.; and a vacuum heat treatment time of 3-30 minutes, and preferably 5-20 minutes; and
preferably, when the upper conductive metal film and the lower conductive metal film are each independently a copper film, the operating conditions of the vacuum heat treatment comprise: a vacuum degree higher than 133 Pa, a vacuum heat treatment temperature of 100-600° C., and preferably 100-500° C.; and a vacuum heat treatment time of 3-30 minutes, and preferably 5-20 minutes.

15. The method for preparing the composite current collector according to claim 10, further comprising coating an adhesive on the polymer layer, and then depositing primer layers and/or conductive layers;
preferably, the preparation method comprises the following steps:
(1) applying an adhesive to the upper surface and the lower surface of the polymer layer, to obtain a first intermediate having a structure of upper bonding layer-polymer layer-lower bonding layer; and
(2) preparing an upper conductive layer on the upper bonding layer, and preparing a lower conductive layer on the lower bonding layer, to obtain a composite current collector having a structure of upper conductive layer-upper bonding layer-polymer layer-lower bonding layer-lower conductive layer; and
preferably, the preparation method comprises the following steps:
(1) applying an adhesive to the upper surface and the lower surface of the polymer layer, to obtain a first intermediate having a structure of upper bonding layer-polymer layer-lower bonding layer;
(2) preparing an upper primer layer on the upper bonding layer, and preparing a lower primer layer on the lower bonding layer, to obtain a second intermediate having a structure of upper primer layer-upper bonding layer-polymer layer-lower bonding layer-lower primer layer; and
(3) preparing an upper conductive layer on the upper primer layer, and preparing a lower conductive layer on the lower primer layer, to obtain a composite current collector having a structure of upper conductive layer-upper primer layer-upper bonding layer-polymer layer-lower bonding layer-lower primer layer-lower conductive layer.

16. Use of the composite current collector described in claim 1 or the composite current collector prepared by the preparation method described in claim 10 in a lithium-ion battery.
